(19) United States
(12) Patent Application Publication
(10) Pub. No.: US 2008/0112136 A1
(43) Pub. Date: May 15, 2008

(54) CIRCUIT BOARD ADAPTED TO FAN AND FAN STRUCTURE

(75) Inventors: Yu-Liang Lin, Pingtung (TW); Yu-Lung Dung, Taoyuan (TW); Yueh-Lung Huang, Miaoli (TW); Chen-Lin Huang, Kaohsiung (TW)

Correspondence Address: PAI PATENT & TRADEMARK LAW FIRM, 1001 FOURTH AVENUE, SUITE 3200, SEATTLE, WA, 98154, US

(73) Assignee: DELTA ELECTRONICS, INC., Taoyuan County (TW)

(21) Appl. No.: 12/013,228

(22) Filed: Jan. 11, 2008

Related U.S. Application Data
(62) Division of application No. 10/797,854, filed on Mar. 10, 2004.

(30) Foreign Application Priority Data
Apr. 11, 2003 (TW) 92205657

(51) Int. Cl. H05K 7/20

(52) U.S. Cl. 361/697

(57) ABSTRACT

A circuit board adapted to a fan comprises a circuit region and a heat-dissipative film. The circuit region is provided on a first surface of the circuit board and comprises at least one heat-generating component thereon. The heat-dissipative film is coated on an edge portion of the first surface and is in contact with the heat-generating component. A plurality of openings through the heat-dissipative film, a protrusion of the circuit board, a cutout in the protrusion to expose the heat-generating component to airflow, etc., have been disclosed and claimed for enhancing the efficiency in heat dissipation. A heat sink may also be provided on a second surface opposite to the first surface of the circuit board. The heat sink is connected to the heat-dissipative film to help dissipate the heat generated by the operation of the fan.

### RELATED APPLICATIONS

This application is a divisional application of U.S. application Ser. No. 10/797,854, filed Mar. 10, 2004, the full disclosure of which is incorporated herein by reference.

### BACKGROUND OF THE INVENTION

1. Field of the Invention

The invention relates to a circuit board adapted to a fan and a fan structure, and, more particularly, to a circuit board that possesses an enhanced efficiency in heat dissipation and a fan structure provided with the same.

2. Description of the Related Art

Generally, a conventional fan is operated by a circuit board to drive a motor for activating a hub and fan blades thereof to generate airflow at a certain speed. Accordingly, the heat generated by a heat-generating device provided with the fan can be dissipated by the airflow.

However, after the fan is operated for a certain period of time, the efficiency in heat dissipation of the fan will deteriorate because during operation the electronic components of the fan also generate heat which cannot be readily dispersed away from the fan structure.

Usually, the integrated circuit of the cooling fan used in a notebook computer operates in a single-phase bipolar mode. In this case, regardless of the amount of operable current of the integrated circuit, since the current flows directly into the integrated circuit, it always results in considerable heat. When the heat cannot be dispersed efficiently, it will accumulate and thus causes problems such as overheating and shutdown of the notebook computer.

### BRIEF SUMMARY OF THE INVENTION

In view of the aforementioned problems, an object of the invention is to provide a circuit board adapted to a fan for improving the efficiency in heat dissipation and increasing the operable current range of the electronic components mounted thereon.

Another object of the invention is to provide a fan structure using the aforementioned circuit board for extending the lifetime of a fan.

To achieve the objects, the invention provides a circuit board adapted to a fan comprising a circuit region and a heat-dissipative film. The circuit region is located on one surface of the circuit board and includes a plurality of pads for mounting at least one heat-generating component thereon. The heat-dissipative film is coated on an edge portion of the same surface as the circuit region is located on and is in contact with the heat-generating component.

Preferably, the circuit region is surrounded by the heat-dissipative film, and the heat-dissipative film is formed with a plurality of openings. Besides, the heat-dissipative film is a coating film made of heat-conducting material; specifically, the heat-conducting material is selected from the group consisting of copper, aluminum, iron, and an alloy thereof.

Moreover, the circuit board of the invention may further include a heat sink located on a second surface opposite to the aforementioned surface of the circuit board. Besides, another circuit region may be provided on the second surface of the circuit board. The heat sink is connected to the heat-dissipative film via the openings. The heat sink is formed by coating a heat-conducting material on an edge portion of the second surface; specifically, the heat-conducting material is selected from the group consisting of copper, aluminum, iron, and an alloy thereof.

Furthermore, the circuit board may be provided with a protrusion on which the heat-generating component and/or the heat-dissipative film may be formed. Besides, the protrusion may have a cutout which extends over the length of the heat-generating component.

In addition, the invention also provides a fan structure that includes a hub, a motor located inside the hub, a plurality of fan blades connected to the hub, and a circuit board connected to the motor. Specifically, the fan structure is characterized by the circuit board, which comprises a circuit region and a heat-dissipative film. In more detail, the circuit region is located on one surface of the circuit board and has at least one heat-generating component mounted thereon. The heat-dissipative film is coated on an edge portion of the same surface as the circuit region located on and is in contact with the heat-generating component.

The circuit board of the invention is provided with the heat-dissipative film and optionally the heat sink, thus the heat generated by the heat-generating component can be readily dissipated by the heat-dissipative film or the heat sink, so that it is possible to dramatically enhance the efficiency in heat dissipation.

Also, according to the fan structure of the invention, the heat-dissipative film and/or the heat sink may extend outside the circumference of the hub, thus the heat dissipated from the heat-dissipative film and/or the heat sink can be further dispersed by an airflow generated by the fan. Therefore, it is possible not only for the circuit board to have an enhanced efficiency in heat dissipation and therefore an increased operable current range of the electronic components mounted thereon, but also for the fan provided with the same to have a prolonged lifetime.

Still further, in the case that the protrusion of the circuit board is protruded outwardly with respect to the hub, since the heat-generating component provided on the protrusion is exposed to the airflow of the fan, the heat of the heat-generating component can be dispersed rapidly. Therefore, it is possible not only for the circuit board to enhance its efficiency in heat dissipation and therefore to increase the operable current range of the electronic components mounted thereon, but also for the fan provided with the circuit board to have a prolonged lifetime.

Other aspects and advantages of the invention will become apparent from the following detailed description in conjunction with the accompanying drawings, which illustrate by way of example the principles of the invention.

### BRIEF DESCRIPTION OF THE DRAWINGS

FIG. 1 is a schematic diagram showing the circuit board according to the first embodiment of the invention.

FIG. 2 is a schematic diagram showing the fan provided with the circuit board of the invention.

FIG. 3 is a schematic diagram showing the circuit board according to the second embodiment of the invention.

FIG. 4 is a schematic diagram showing the heat sink linked with the circuit board of the invention.

FIG. 5 is a cross-sectional view taken along the line 5-5 of FIG. 4.

FIG. 6 is a schematic diagram showing the circuit board according to the third embodiment of the invention.

FIG. 7 is a schematic diagram showing the circuit board according to the fourth embodiment of the invention.

FIG. 8 is a schematic diagram showing the circuit board according to the fifth embodiment of the invention.

### DETAILED DESCRIPTION OF THE PREFERRED EMBODIMENTS

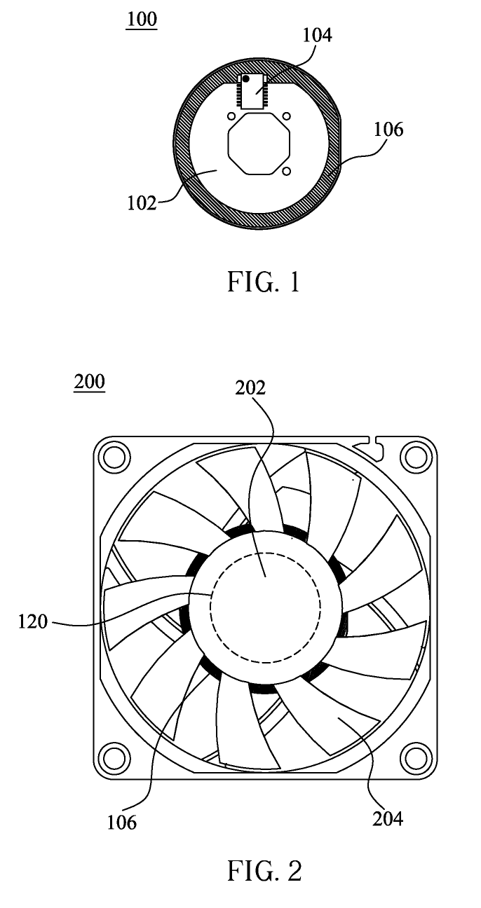

FIG. 1 is a schematic diagram showing the circuit board according to the first embodiment of the invention, and FIG. 2 is a schematic diagram showing a fan provided with the circuit board. As shown in FIGS. 1 and 2, a fan structure 200 of the invention includes a hub 202, a motor 120 located inside the hub 202, a plurality of fan blades 204 connected to the hub 202, and a circuit board 100 connected to the motor 120.

The hub 202 is coupled to the motor 120 so as to rotate synchronously with the motor 120 and drive the fan blades 204 to rotate accordingly. When the fan blades 204 rotate, an airflow flowing through the fan structure 200 is generated.

It should be understood that the various shapes and materials of the hub 202, motor, and the fan blades 204 can be chosen to meet the actual requirements. It will be obvious, however, to one skilled in the art, that the present invention may be practiced without some or all of these specific details. In other instances, the specific details have been omitted to avoid misinterpretation of the present invention.

The circuit board 100 comprises a circuit region 102 and a heat-dissipative film 106, wherein the heat-dissipative film 106 is located on the edge of the circuit board 100. The circuit region 102 includes circuits, semiconductor devices, integrated circuits and related components for driving the motor connected to the circuit board. Some of the components, such as the integrated circuit and semiconductor devices, can be grouped into a heat-generating component 104.

To be specific, the heat-dissipative film 106 is in contact with the heat-generating component 104 for dissipating the heat generated by the heat-generating component 104. Moreover, the heat of the heat-dissipative film 106 can be readily dispersed by means of airflow generated in the fan structure 200. The heat-dissipative film 106, for example, is a coating film made of heat-conducting material, wherein the heat-conducting material is selected from the group consisting of copper, aluminum, iron, and an alloy thereof.

Moreover, the heat-dissipative film 106 is provided to surround the circuit region 102. The heat-dissipative film 106 can also be located on any region of the circuit board 100 other than on the circuit region 102. Besides, the heat-dissipative film 106 may extend outside the circumference of the hub 202 as shown in FIG. 2, or may be limited to inside the circumference of the hub 202. When the heat-dissipative film 106 extends outside the circumference of the hub 202 so that the heat-dissipative film 106 is located in the air passage of the fan structure 200, the airflow passing by the heat-dissipative film 106 can readily disperse the heat dissipated from the heat-dissipative film 106. Therefore, it is possible not only for the circuit board 100 to have an enhanced efficiency in heat dissipation and therefore an increased operable current range of the electronic components mounted thereon, but also for the fan structure 200 provided with the circuit board 100 to have a prolonged lifetime.

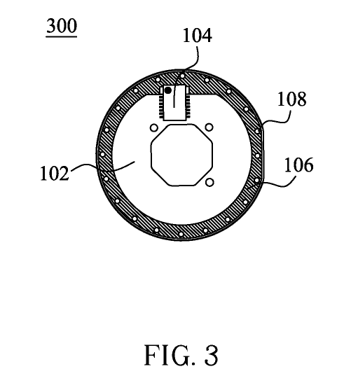

As shown in FIG. 3, the heat-dissipative film 106 of a circuit board 300 is formed with a plurality of openings 108. Preferably, the openings 108 are symmetrically arranged. According to the second embodiment of the invention, the openings 108 of the heat-dissipative film 106 are formed in order to serve as a portion of the air passage in the operating fan structure 200, thus the heat dissipated from the heat-dissipative film 106 can be readily dispersed by the airflow passing through the openings 108. Therefore, it is possible not only for the circuit board 300 to have an enhanced efficiency in heat dissipation and therefore an increased operable current range of the electronic components mounted thereon, but also for the fan structure 200 provided with the circuit board 300 to have a prolonged lifetime.

Moreover, according to the structure of the circuit board 100, a heat sink (not shown) is further formed on the surface opposite to the surface of the circuit board 100 provided with the heat-dissipative film 106. The heat sink is connected to the heat-dissipative film 106 via a plurality of protruding portions of the heat sink, wherein the airflow passing through a plurality of through holes or the openings 108 thereof as shown in FIG. 3, so that the total area for heat dissipation of the heat-dissipative film 106 can be increased. The heat sink, for example, can be a sheet or a coating film made of heat-conducting material, which is selected from the group consisting of copper, aluminum, iron, and an alloy thereof.

Also, various shapes of the heat sink may be chosen to meet the actual requirements, such as a shape corresponding to the outline of the circuit board 100 or any other shapes. In addition, if another circuit region (not shown) is formed on the other surface of the circuit board, the heat sink can be located at any region of the circuit board 100 other than the circuit region.

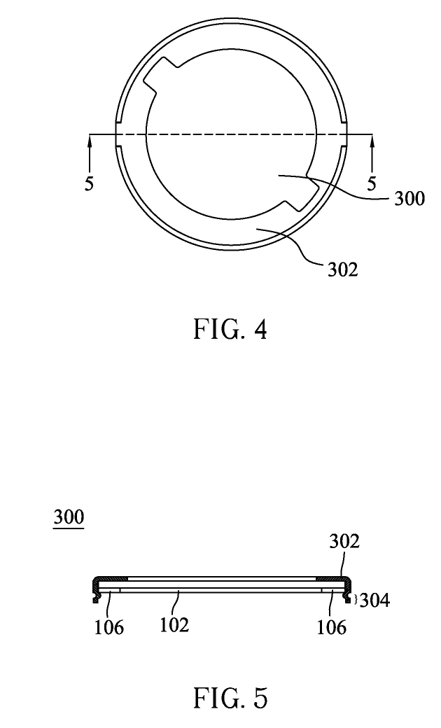

Alternatively, as shown in FIGS. 4 and 5, the heat sink 302 is engaged with the circuit board 300 by sheet-metal working and connected with the heat-dissipative film 106. For instance, a fastening portion 304 is formed on the heat sink 302, and then the heat sink 302 is directly engaged with the circuit board 300 via clamping or fastening and then connected to the heat-dissipative film 106 through the fastening portion 304.

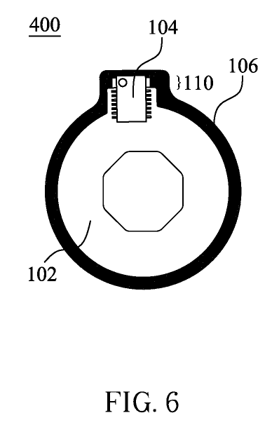

Moreover, as shown in FIG. 6, the circuit board 400 is provided with a protrusion 110, wherein a heat-generating component 104 is located on the protrusion 110. In this embodiment, either only the protrusion 110 of the circuit board 400 extends outside the circumference of the hub 202 or both of the protrusion 110 and the heat-dissipative film 106 extend outside the circumference of the hub 202. Even in the case where only the protrusion 110 extends outside the circumference of the hub 202, because the protrusion 110 is located directly in the air passage of the fan structure 200, it is possible to dissipate the heat generated by the heat-generating component 104 by the airflow passing past the protrusion 110. Therefore, it is possible not only for the circuit board 400 to have an enhanced efficiency in heat dissipation and therefore an increased operable current range of the electronic components mounted thereon, but also for the fan structure 200 provided with the circuit board 400 to have a prolonged lifetime.

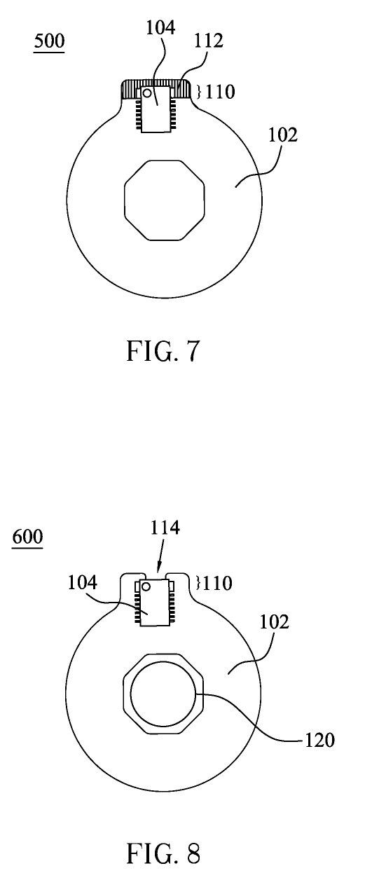

Alternatively, the heat-dissipative film 112 on the circuit board 500 is formed on the protrusion 110 as shown in FIG. 7, or the heat-generating component 104 is mounted on the protrusion 110 of the circuit board 500 alone. In this case, the heat generated by the heat-generating component 104 can still be dispersed by the air flowing past the protrusion 110. Therefore, it is possible not only for the circuit board 500 to have an enhanced efficiency in heat dissipation and therefore an increased operable current range of the electronic components mounted thereon, but also for the fan structure 200 provided with the circuit board 500 to have a prolonged lifetime.

Furthermore, in order to enhance the efficiency in heat dissipation of the circuit board 500, a cutout 114 is formed through the protrusion 110 of a circuit board 600 as shown in FIG. 8 to extend over the length of the heat-generating component 104. In this case, a portion of the heat-generating component 104 is exposed to the air passage via the cutout 114. Therefore, according to this embodiment, the heat-generating component 104 is almost entirely exposed to the air passage, thus the heat-generating component 104 has a greater contact area with the airflow. Hence, the heat generated by the heat-generating component 104 is readily dispersed by the air flowing past the protrusion 110. Therefore, it is possible not only for the circuit board 600 to have an enhanced efficiency in heat dissipation and therefore an increased operable current range of the electronic components mounted thereon, but also for the fan structure 200 provided with the circuit board 600 to have a prolonged lifetime.

In conclusion, the circuit board of the invention is provided with a heat-dissipative film and/or a heat sink and thus the heat generated by the heat-generating component can be readily dispersed. Therefore, the efficiency in heat dissipation of the circuit board can be greatly enhanced.

Also, according to the fan structure of the invention, the heat-dissipative film may extend outside the circumference of the hub, thus the heat generated by the heat-generating component and dissipated to the heat-dissipative film and/or the heat sink can be readily dispersed by the airflow. Therefore, not only is the efficiency in heat dissipation and therefore the operable current range of the electronic components mounted thereon enhanced, but also the fan structure provided with the circuit board will have a prolonged lifetime.

Moreover, in the case where the protrusion of the circuit board extends outside the circumference of the hub, the heat generated by the operating fan can be readily dispersed because the heat-generating component is exposed to the airflow. Therefore, not only is the efficiency in heat dissipation and therefore the operable current range of the electronic components mounted thereon enhanced, but also the fan structure provided with the circuit board will have a prolonged lifetime.

Although the foregoing invention has been described in some detail for purposes of clarity and ease of understanding, it is apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A fan structure comprising a hub, a motor located inside the hub, a plurality of fan blades connected to the hub, and a circuit board connected to the motor, wherein the circuit board comprises:
a circuit region provided on a first surface of the circuit board, the circuit region comprising at least one heat-generating component thereon; and
a heat-dissipative film coated on an edge portion of the first surface and in contact with the heat-generating component.

2. The fan structure as claimed in claim 1, wherein the circuit region is surrounded by the heat-dissipative film.

3. The fan structure as claimed in claim 1, wherein the heat-dissipative film extends outside the circumference of the hub.

4. The fan structure as claimed in claim 1, wherein the heat-dissipative film is formed with a plurality of openings.

5. The fan structure as claimed in claim 1, further comprising a heat sink located on a second surface of the circuit board opposite to the first surface of the circuit board.

6. The fan structure as claimed in claim 5, wherein the heat sink is connected to the heat-dissipative film by means of a plurality of through holes and a fastening portion.

7. The fan structure as claimed in claim 1, wherein the first surface of the circuit board comprises a protrusion for carrying the heat-generating component and optionally the heat-dissipative film, and the protrusion extends outside the circumference of the hub.

8. The fan structure as claimed in claim 7, wherein the protrusion has a cutout that extends from a tip of the protrusion to the heat-generating component.

9. The fan structure as claimed in claim 7, wherein the protrusion has a cutout that extends over a portion of the heat-generating component so that the portion of the heat-generating component is exposed via the cutout in the protrusion.

10. A circuit board for operating a fan, comprising:
a circuit region provided on a first surface of the circuit board and including at least one heat-generating component thereon; and
a heat-dissipative film coated on an edge portion of the first surface and in contact with the heat-generating component.

11. The circuit board as claimed in claim 10, wherein the circuit region is surrounded by the heat-dissipative film.

12. The circuit board as claimed in claim 10, wherein the heat-dissipative film is formed with a plurality of openings.

13. The circuit board as claimed in claim 10, further comprising a heat sink provided on a second surface of the circuit board opposite to the first surface of the circuit board.

14. The circuit board as claimed in claim 13, wherein the heat sink is connected to the heat-dissipative film by means of a plurality of through holes and a fastening portion.

15. The circuit board as claimed in claim 13, wherein the heat sink is selected from the group consisting of a heat-conducting film and a heat-conducting sheet.

16. The circuit board as claimed in claim 10, wherein the first surface of the circuit board comprises a protrusion and the at least one heat-generating component is mounted over the protrusion of the first surface.

17. The circuit board as claimed in claim 16, wherein the protrusion has a cutout that extends from a tip of the protrusion to the heat-generating component and optionally to the heat-dissipative film.

18. The circuit board as claimed in claim 10, wherein the heat-dissipative film is formed by a coating film made of heat-conducting material.
